(19) United States
(12) Patent Application Publication
(10) Pub. No.: US 2024/0047963 A1
(43) Pub. Date: Feb. 8, 2024

(54) RESET CIRCUIT

(71) Applicant: KABUSHIKI KAISHA TOKAI RIKA DENKI SEISAKUSHO, Aichi (JP)

(72) Inventor: Yoshihiko SATO, Aichi (JP)

(21) Appl. No.: 18/225,971

(22) Filed: Jul. 25, 2023

(30) Foreign Application Priority Data
Aug. 5, 2022 (JP) 2022-125328

(51) Int. Cl. H02H 7/18; B60R 16/033; H01M 10/42; H01M 10/48; G01R 19/165

(52) U.S. Cl. CPC H02H 7/18; B60R 16/033; H01M 10/425; H01M 10/48; G01R 19/16542; H01M 2220/20

(57) ABSTRACT

A reset circuit includes a first voltage generation unit that generates a first voltage based on a first power supply voltage output from a first constant voltage source, and a comparator that includes a positive power supply terminal to which the first voltage is input, a negative power supply terminal connected to a ground circuit, one input terminal as one of positive and negative input terminals and to which a reference voltage is input, another input terminal as the other of the positive and negative input terminals and to which a divided voltage obtained by dividing a second power supply voltage supplied from a second constant voltage source different from the first constant voltage source and to be detected based on the reference voltage is input, and an output terminal that outputs a reset signal to reset a subsequent circuit to the initial state according to a comparison result.

### CROSS-REFERENCE TO RELATED APPLICATIONS

The present patent application claims the priority of Japanese patent application No. 2022/125328 filed on Aug. 5, 2022, and the entire contents of Japanese patent application No. 2022/125328 are hereby incorporated by reference.

### TECHNICAL FIELD

The present invention relates to a reset circuit.

### BACKGROUND ART

A semiconductor integrated circuit device is known which is provided with a voltage step-up means that operates with, as a power supply, a first voltage supplied to an external power supply terminal to operate an internal circuit having a desired function and outputs a second voltage obtained by stepping up the first voltage at a predetermined ratio, a voltage detecting means that operates with this second voltage as a power supply, compares a divided voltage obtained by dividing the second voltage to a predetermined reference voltage and outputs a first comparison result signal, and a level shift means that operates with the first voltage as a power supply and outputs a second comparison result signal obtained by changing the level of the first comparison result signal (see, e.g., Patent Literature 1).

In the semiconductor integrated circuit device, the second comparison result signal becomes a reset signal for resetting the internal circuit when the divided voltage is lower than the reference voltage.

### CITATION LIST

### Patent Literature

Patent Literature 1: JP 2002/41159A

### SUMMARY OF INVENTIONS

In the known semiconductor integrated circuit device, the second voltage generated from the first voltage is used as the power supply to operate the voltage detecting means. Therefore, if the first voltage becomes 0 V due to short circuit, etc., the voltage detecting means does not operate, the circuit malfunctions, and the reset signal is not output.

It is an object of the invention to provide a reset circuit that can suppress the malfunction of the circuit.

An aspect of the invention provides a reset circuit, comprising:
a first voltage generation unit that generates a first voltage based on a first power supply voltage output from a first constant voltage source; and
a comparator that comprises a positive power supply terminal to which the first voltage is input, a negative power supply terminal connected to a ground circuit, one input terminal which is one of a positive input terminal and a negative input terminal and to which a reference voltage is input, another input terminal which is the other of the positive input terminal and the negative input terminal and to which a divided voltage obtained by dividing a second power supply voltage supplied from a second constant voltage source different from the first constant voltage source and to be detected based on the reference voltage is input, and an output terminal that outputs a reset signal to reset a subsequent circuit to the initial state according to a comparison result.

### Advantageous Effects of Invention

According to the invention, it is possible to suppress the malfunction of the circuit.

### BRIEF DESCRIPTION OF DRAWINGS

FIG. 1A is an example of a circuit diagram illustrating a reset circuit.

FIG. 1B is an example of a block diagram related to the reset circuit.

FIG. 2A is a diagram illustrating an example of a reference voltage and a divided voltage.

FIG. 2B is a diagram illustrating an example of a relationship between Hi and Lo of a reset signal.

FIG. 3 is a circuit diagram illustrating an example of the reset circuit.

### DESCRIPTION OF EMBODIMENTS

### Short Summary of the Embodiments

A reset circuit in the embodiments is generally composed of a first voltage generation unit that generates a first voltage based on a first power supply voltage output from a first constant voltage source, and a comparator that has a positive power supply terminal to which the first voltage is input, a negative power supply terminal connected to a ground circuit, one input terminal which is one of a positive input terminal and a negative input terminal and to which a reference voltage is input, another input terminal which is the other of the positive input terminal and the negative input terminal and to which a divided voltage obtained by dividing a second power supply voltage supplied from a second constant voltage source different from the first constant voltage source and to be detected based on the reference voltage is input, and an output terminal that outputs a reset signal to reset a subsequent circuit to the initial state according to a comparison result.

In this reset circuit, the first voltage to operate the comparator and the second power supply voltage to be detected are generated from different constant voltage sources. Therefore, as compared to when these voltages are generated from the same constant voltage source, it is possible to suppress the malfunction of the circuit.

### First Embodiment

### (General Configuration of a Reset Circuit 1)

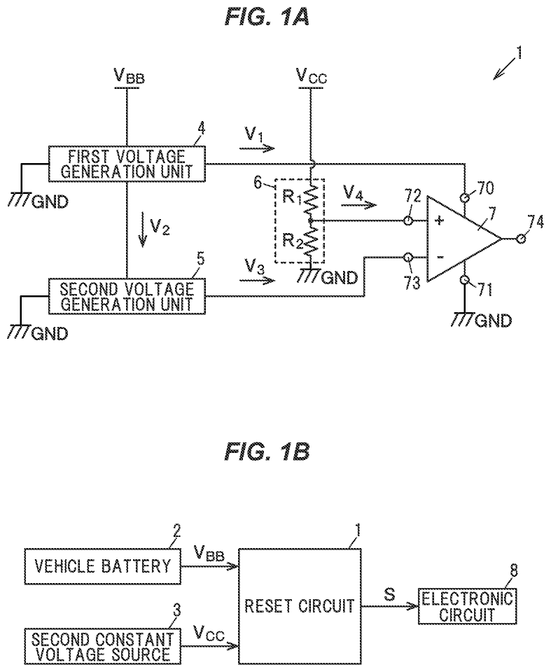

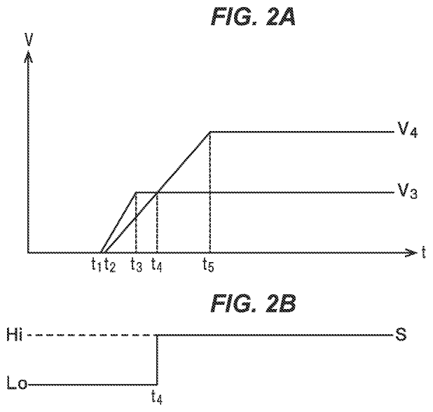

FIG. 1A is an example of a circuit diagram illustrating a reset circuit in the first embodiment, and FIG. 1B is an example of a block diagram related to the reset circuit. FIG. 2A is a diagram illustrating an example of a reference voltage and a divided voltage in the first embodiment, and FIG. 2B is a diagram illustrating an example of a relationship between Hi and Lo of a reset signal. In FIG. 2A, the vertical axis indicates voltage V and the horizontal axis indicates time t. Constant voltage also includes voltage that fluctuates within an acceptable range.

As shown in FIGS. 1A and 1B, the reset circuit 1 is generally composed of a first voltage generation unit 4 that generates a first voltage V₁ based on a first power supply voltage V_{BB} output from a first constant voltage source, and a comparator 7 that has a positive power supply terminal 70 to which the first voltage V₁ is input, a negative power supply terminal 71 connected to a ground circuit GND, one input terminal which is one of a positive input terminal 72 and a negative input terminal 73 and to which a reference voltage V₃ is input, another input terminal which is the other of the positive input terminal 72 and the negative input terminal 73 and to which a divided voltage V₄ obtained by dividing a second power supply voltage V_{CC} supplied from a second constant voltage source 3 different from the first constant voltage source and to be detected based on the reference voltage V₃ is input, and an output terminal 74 that outputs a reset signal S to reset a subsequent circuit to the initial state according to a comparison result.

The reset circuit 1 further includes a second voltage generation unit 5 that generates the reference voltage V₃ based on a second voltage V₂ generated by the first voltage generation unit 4.

In the reset circuit 1 of the first embodiment, the reference voltage V₃ is input to the negative input terminal 73 as one input terminal, and the divided voltage V₄ is input to the positive input terminal 72 as another input terminal. As a modification, the reset circuit 1 may be configured such that the reference voltage V₃ is input to the positive input terminal 72 as one input terminal and the divided voltage V₄ is input to the negative input terminal 73 as another input terminal. In this modification, the reset signal S to reset a subsequent circuit to the initial state is output during when, e.g., the divided voltage V₄ is lower than the reference voltage V₃.

As shown in FIG. 1A, the reset circuit 1 has a voltage divider 6. The voltage divider 6 divides the second power supply voltage V_{CC} and thereby generates the divided voltage V₄.

The subsequent circuit is, e.g., an electronic circuit 8. As an example, the electronic circuit 8 is a microcomputer for on-board device mounted on a vehicle and is composed of a CPU (Central Processing Unit), and a RAM (Random Access Memory) and a ROM (Read Only Memory) which are semiconductor memories, etc. but it is not limited thereto. The reset circuit 1, together with the second constant voltage source 3 and the microcomputer, is formed as one chip, as an example.

### (Configuration of the First Constant Voltage Source)

As shown in FIG. 1B, the first constant voltage source is a vehicle battery 2. Therefore, the first power supply voltage V_{BB} is a battery voltage of the vehicle battery 2. The first power supply voltage V_{BB} is 12V, as an example. In this regard, the first constant voltage source is not limited to the vehicle battery 2 and may be any constant voltage source different from the second constant voltage source 3.

### (Configuration of the Second Constant Voltage Source 3)

The second constant voltage source 3 is configured to generate, e.g., the second power supply voltage V_{CC} to operate the electronic circuits 8, based on the first power supply voltage V_{BB} supplied from the vehicle battery 2. The second power supply voltage V_{CC} is, e.g., 3.5V to 5V, but it is not limited thereto.

As a modification, the first constant voltage source and the second constant voltage source 3 may be configured so that the first power supply voltage V_{BB} and the second power supply voltage V_{CC} are generated from different batteries mounted on the vehicle, not from the same vehicle battery 2.

### (Configuration of the First Voltage Generation Unit 4)

The first voltage generation unit 4 is configured as a startup circuit that steps the first power supply voltage V_{BB} down and thereby generates the stable first voltage V₁. The first voltage generation unit 4 in the first embodiment further generates the stable second voltage V₂. The first voltage V₁ and the second voltage V₂ are constant voltages and, as an example, are different from each other.

The first voltage generation unit 4 is electrically connected to the ground circuit GND. In addition, the first voltage generation unit 4 is electrically connected to the second voltage generation unit 5 and is also electrically connected to the comparator 7.

### (Configuration of the Second Voltage Generation Unit 5)

The second voltage generation unit 5 is configured as a bandgap reference circuit that generates the reference voltage V₃ with suppressed fluctuation. The second voltage generation unit 5 is electrically connected to the ground circuit GND. In addition, the second voltage generation unit 5 is electrically connected to the first voltage generation unit 4 and is also electrically connected to the comparator 7.

### (Configuration of the Voltage Divider 6)

As shown in FIG. IA, the voltage divider 6 is electrically connected between the second constant voltage source 3 and the ground circuit GND. The voltage divider 6 is composed of, e.g., a resistor R₁ and a resistor R₂. The resistors R₁ and R₂ are connected in series. Therefore, the divided voltage V₄ is a midpoint potential between the resistors R₁ and R₂. The resistors R₁ and R₂ have the same resistance value as an example, but it is not limited thereto.

### (Configuration of the Comparator 7)

The comparator 7 compares the divided voltage V₄ input to the positive input terminal 72 with the reference voltage V₃ input to the negative input terminal 73 as shown in FIGS. 2A and 2B. The reset signal S is Lo when the divided voltage V₄ is less than the reference voltage V₃, and the reset signal S is Hi when the divided voltage V₄ is not less than the reference voltage V₃.

That is, the comparator 7 is configured to output a Lo reset signal S for a predetermined period of time after starting power supply so that the circuit does not operate unintentionally at the time of starting power supply and during when the voltage is unstable. The electronic circuit 8 is reset to the initial state when the reset signal S is Lo.

As shown in FIG. 2A, the reference voltage V₃ rises at time t₁, increases until time t3, and becomes stable. Meanwhile, since the second power supply voltage V_{CC} is generated based on the reference voltage V₃, the divided voltage V₄ rises at time t₂ with a delay from the reference voltage V₃, increases until time t₅, and becomes stable. The divided voltage V₄ is higher than the reference voltage V₃, hence, in case that it becomes equipotential at time t₄, the divided voltage V₄ becomes higher than the reference voltage V₃ after time t₄. Therefore, the reset signal S switches from Lo to Hi at time t₄, as shown in FIG. 2B.

(Operation of the Reset Circuit 1 when the Second Power Supply Voltage V_{CC} is Short-Circuited)

In the reset circuit 1, when the second constant voltage source 3 is short-circuited to the ground circuit GND and the second power supply voltage V_{CC} becomes 0 V, the divided voltage V₄ also becomes 0 V.

Therefore, the divided voltage V₄ of 0 V is input to the positive input terminal 72 of the comparator 7, and the reference voltage V₃ of 1.2 V is input to the negative input terminal 73 of the comparator 7. That is, the divided voltage V₄ remains lower than the reference voltage V₃. The comparator 7 thus outputs the Lo reset signal S, hence, the electronic circuit 8 remains in the initial state without being accidentally activated even if the second power supply voltage V_{CC} becomes 0 V due to short circuit, etc.

### (Effects of The First Embodiment)

The reset circuit 1 in the first embodiment can suppress the malfunction of the circuit. This reset circuit 1 is a circuit that outputs the reset signal S to reset the electronic circuit 8 to the initial state so that the electronic circuit 8 is not activated during when the second power supply voltage V_{CC} to operate the electronic circuit 8 is low voltage. In the reset circuit 1, the first voltage V₁ to operate the comparator 7 is generated from the first power supply voltage V_{BB} of the vehicle battery 2 and the divided voltage V₄ obtained by dividing the second power supply voltage V_{CC} to be detected is generated from the second constant voltage source 3. Therefore, as compared to when these voltages are generated from the same constant voltage source, the reset circuit 1 can suppress the malfunction of the circuit since even if the second supply voltage V_{CC} becomes 0 V due to short circuit, etc., the comparator 7 can operate and output the reset signal S to reset the electronic circuit 8 to the initial state so that the electronic circuit 8 is not activated.

In the reset circuit 1, the first voltage generation unit 4 is a startup circuit, the second voltage generation unit 5 is a bandgap reference circuit, and the stable first voltage V₁, second voltage V₂ and reference voltage V₃ can be generated. Therefore, as compared to when such a configuration is not adopted, detection accuracy when the second power supply voltage V_{CC} is low voltage can be improved.

In the reset circuit 1, the first voltage Vi to operate comparator 7 and the reference voltage V₃ are generated based on the first power supply voltage V_{BB} output from the vehicle battery 2. Therefore, voltage stability is higher as compared to when such a configuration is not adopted.

### Second Embodiment

The second embodiment differs from the first embodiment in that the first voltage generation unit supplies the same voltage to the second voltage generation unit and the comparator.

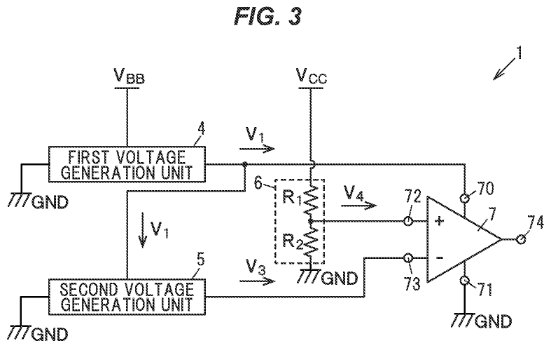

FIG. 3 is a circuit diagram illustrating an example of the reset circuit in the second embodiment. In the embodiment described below, portions having the same functions and configurations as those in the first embodiment are denoted by the same reference signs as those in the first embodiment and the explanation thereof will be omitted.

As shown in FIG. 3, the reset circuit 1 in the second embodiment is generally configured so that the first voltage V₁ generated by the first voltage generation unit 4 is supplied to the second voltage generation unit 5 and the comparator 7. The second voltage generation unit 5 generates the reference voltage V₃ based on the input first voltage V₁.

In this reset circuit 1, even if the second power supply voltage V_{CC} unintentionally becomes 0 V due to short circuit, etc., the comparator 7 can output the Lo reset signal S to the electronic circuit 8 since the comparator 7 operates with the first voltage V₁ which is not affected by the second power supply voltage V_{CC}. The electronic circuit 8 is reset to the initial state by this reset signal S, and unintended erroneous operation can be suppressed.

Although some embodiments and modifications of the invention have been described, these embodiments and modifications are merely examples and the invention according to claims is not to be limited thereto. These new embodiments and modifications may be implemented in various other forms, and various omissions, substitutions and changes, etc., can be made without departing from the gist of the invention. In addition, not all combinations of the features described in these embodiments and modifications are necessary to solve the problem of the invention. Further, these embodiments and modifications are included within the scope and gist of the invention and also within the invention described in the claims and the range of equivalency.

### REFERENCE SIGNS LIST

1 RESET CIRCUIT
2 VEHICLE BATTERY
3 SECOND CONSTANT VOLTAGE SOURCE
4 FIRST VOLTAGE GENERATION UNIT
5 SECOND VOLTAGE GENERATION UNIT
6 VOLTAGE DIVIDER
7 COMPARATOR
8 ELECTRONIC CIRCUIT
70 POSITIVE POWER SUPPLY TERMINAL
71 NEGATIVE POWER SUPPLY TERMINAL
72 POSITIVE INPUT TERMINAL
73 NEGATIVE INPUT TERMINAL
74 OUTPUT lERMINAL

1. A reset circuit, comprising:
a first voltage generation unit that generates a first voltage based on a first power supply voltage output from a first constant voltage source; and
a comparator that comprises a positive power supply terminal to which the first voltage is input, a negative power supply terminal connected to a ground circuit, one input terminal which is one of a positive input terminal and a negative input terminal and to which a reference voltage is input, another input terminal which is the other of the positive input terminal and the negative input terminal and to which a divided voltage obtained by dividing a second power supply voltage supplied from a second constant voltage source different from the first constant voltage source and to be detected based on the reference voltage is input, and an output terminal that outputs a reset signal to reset a subsequent circuit to the initial state according to a comparison result.

2. The reset circuit according to claim 1, further comprising a second voltage generation unit that generates the reference voltage based on a second voltage generated by the first voltage generation unit.

3. The reset circuit according to claim 1, further comprising a second voltage generation unit that generates the reference voltage based on the first power supply voltage.

4. The reset circuit according to claim 2, wherein the first voltage generation unit comprises a startup circuit that steps the first power supply voltage down and thereby generates the first voltage that is stable.

5. The reset circuit according to claim 2, wherein the second voltage generation unit comprises a bandgap reference circuit that generates the reference voltage with suppressed fluctuation.

6. The reset circuit according to claim 1, wherein the first constant voltage source comprises a vehicle battery, and wherein the first power supply voltage comprises a battery voltage of the vehicle battery.

7. The reset circuit according to claim 1, wherein the comparator is configured so as to output the reset signal if the divided voltage is less than the reference voltage.

8. The reset circuit according to claim 1, wherein the comparator is configured so as to output the reset signal if the second constant voltage source is short-circuited to a ground circuit GND so that the second power supply voltage becomes 0 V.

9. The reset circuit according to claim 1, wherein the second constant voltage source is configured to generate the second power supply voltage based on the first power supply voltage.

10. The reset circuit according to claim 1, wherein the subsequent circuit operates with the second power supply voltage.
